(19) United States
(12) Patent Application Publication
(10) Pub. No.: US 2013/0250220 A1
(43) Pub. Date: Sep. 26, 2013

(54) LIQUID CRYSTAL DISPLAY AND MANUFACTURING METHOD THEREOF

(71) Applicants: Chang Ok KIM, Seoul (KR); Yeun Tae KIM, Suwon-si (KR); Hyang-Shik KONG, Seongnam-si (KR); Jae Sul AN, Hwaseong-si (KR); Hyeong Suk YOO, Yongin-si (KR); Chang Oh JEONG, Suwon-si (KR)

(72) Inventors: Chang Ok KIM, Seoul (KR); Yeun Tae KIM, Suwon-si (KR); Hyang-Shik KONG, Seongnam-si (KR); Jae Sul AN, Hwaseong-si (KR); Hyeong Suk YOO, Yongin-si (KR); Chang Oh JEONG, Suwon-si (KR)

(73) Assignee: SAMSUNG DISPLAY CO., LTD., Yongin-City (KR)

(21) Appl. No.: 13/597,942

(22) Filed: Aug. 29, 2012

(30) Foreign Application Priority Data
Mar. 23, 2012 (KR) 10-2012-0030160

(51) Int. Cl. G02F 1/1337; H01L 33/50

(52) U.S. Cl. 349/123; 438/29; 257/E33.06

(57) ABSTRACT

A liquid crystal display includes: a substrate; a thin film transistor on the substrate; a pixel electrode which is connected to a terminal of the thin film transistor; a microcavity layer on the pixel electrode and including an injection hole through which material is provided to the microcavity layer; a supporting layer on the microcavity layer; and a capping layer on the supporting layer. The capping layer covers the injection hole, and the supporting layer includes silicon oxycarbide (SiOC).

This application claims priority to Korean Patent Application No. 10-2012-0030160 filed on Mar. 23, 2012, and all the benefits accruing therefrom under 35 U.S.C. §119, the entire contents of which are incorporated herein by reference.

### BACKGROUND

(a) Field

The invention relates to a liquid crystal display and a manufacturing method thereof.

(b) Description of the Related Art

A liquid crystal display as one of flat panel display devices that are widely used, includes two display panels where field generating electrodes such as a pixel electrode and a common electrode are formed, and a liquid crystal layer interposed between the field generating electrodes.

The liquid crystal display generates an electric field in the liquid crystal layer by applying voltages to the field generating electrodes, to determine orientations of liquid crystal molecules of the liquid crystal layer and control polarization of incident light, thereby displaying an image.

The liquid crystal display having an EM (embedded microcavity) structure is a device in which a sacrificial layer as a photoresist is formed, a supporting member is coated thereon, then the sacrificial layer is removed by an ashing process, and a liquid crystal is filled in an empty space formed by removal of the sacrificial layer for displaying.

In the liquid crystal display having the EM structure, when the sacrificial layer and the supporting member are formed with the same material, the supporting member may be damaged during removal of the sacrificial layer.

### SUMMARY

The invention provides a liquid crystal display and a manufacturing method thereof that stabilize and simplify a manufacturing process.

An exemplary embodiment of a liquid crystal display according to the invention includes: a substrate; a thin film transistor disposed on the substrate; a pixel electrode which is connected to a first terminal of the thin film transistor; a microcavity layer disposed on the pixel electrode and including an injection hole through which material is provided to the microcavity layer, a supporting layer on the microcavity layer; and including silicon oxycarbide; and a capping layer on the supporting layer wherein the capping layer covers the injection hole.

The capping layer may contact an upper surface of the supporting layer.

The microcavity layer may include a liquid crystal material.

The liquid crystal display may include a plurality of pixel areas. The microcavity layer may include a plurality of regions corresponding to the pixel areas. A groove may be between adjacent regions of the microcavity layer, and the capping layer may cover the groove.

The liquid crystal display may further include a signal line which is connected to a second terminal of the thin film transistor. The groove may extend in a first direction parallel to an extending direction of the signal line.

An opening part may be disposed between regions of the microcavity layer which are adjacent to each other in the first direction. The opening part extends in a second direction which intersects the first direction. The supporting member may cover the opening part.

A common electrode may be disposed between the microcavity layer and the supporting layer.

An alignment layer may be disposed between one of the pixel electrode and the microcavity layer, and between the supporting layer and the microcavity layer.

Another exemplary embodiment of a liquid crystal display according to the invention includes: a substrate; a thin film transistor disposed on the substrate; a pixel electrode which is connected to a first terminal of the thin film transistor; a microcavity layer disposed on the pixel electrode and including an injection hole through which material is provided to the microcavity layer, a supporting member disposed on the microcavity layer; and a capping layer disposed on the supporting layer and covering the liquid crystal injection hole. The capping layer contacts an upper surface of the supporting layer.

The supporting member may include silicon oxycarbide.

The microcavity layer may include a liquid crystal material.

The liquid crystal layer may further include a plurality of pixel areas. The microcavity layer may include a plurality of regions corresponding to the pixel areas. A groove may be between adjacent regions of the microcavity layer, and the capping layer may cover the groove.

The liquid crystal layer may further include a signal line which is connected to a second terminal of the thin film transistor. The groove may extend in a first direction parallel to an extending direction of the signal line.

An opening part may be disposed between regions of the microcavity layer adjacent to each other in the first direction. The opening part extends in a second direction which intersects the first direction, and the supporting layer may cover the opening part.

A common electrode may be disposed between the microcavity layer and the supporting layer.

An alignment layer may be disposed between the pixel electrode and the microcavity layer, and between the supporting member and the microcavity layer.

An exemplary embodiment of a method of manufacturing a liquid crystal display includes: providing a thin film transistor on a substrate; providing a pixel electrode on the thin film transistor; providing a sacrificial layer on the pixel electrode; providing a supporting member on the sacrificial layer; removing the sacrificial layer to form a microcavity layer including an injection hole; injecting a liquid crystal material to the microcavity layer; and providing a capping layer on the supporting layer. The capping layer covers the injection hole, and the sacrificial layer and the supporting member include different materials from each other.

Only one of the sacrificial layer and the supporting member may include silicon oxycarbide.

The one of the sacrificial layer and the supporting member including silicon oxycarbide may be formed by using chemical vapor deposition.

The one of the sacrificial layer and the supporting member not including silicon oxycarbide may be formed by using a photoresist.

The method may further include: providing a color filter on the thin film transistor; and providing a light blocking member overlapping an edge of the color filter. The injection hole may be formed to be disposed along an extension direction of the light blocking member.

The capping layer may contact an upper surface of the supporting layer.

The method may further include providing an alignment layer at an outer wall of the microcavity layer before the injecting the liquid crystal material to the microcavity layer.

The method may further include providing a common electrode between the sacrificial layer and the supporting layer.

According to one or more exemplary embodiment of the invention, the sacrificial layer and the supporting member are formed with different materials such that damage to the supporting layer may be reduced or effectively prevented when removing the sacrificial layer. Furthermore, an additional passivation layer may be omitted such that the manufacturing process may be simplified. Moreover, since the capping layer seals the injection hole of the microcavity layer, the liquid crystal display excludes an additional (upper) substrate.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1 is a top plan view of an exemplary embodiment of a liquid crystal display according to the invention.

FIG. 2 is a cross-sectional view taken along line II-II′ of FIG. 1.

FIG. 3 is a cross-sectional view taken along line III-III′ of FIG. 1.

FIG. 4 is a perspective view of an exemplary embodiment of a microcavity layer in FIG. 1 to FIG. 3 according to the invention.

FIG. 5 to FIG. 14 are cross-sectional views of an exemplary embodiment of a manufacturing method of a liquid crystal display according to the invention.

### DETAILED DESCRIPTION

The invention will be described more fully hereinafter with reference to the accompanying drawings, in which exemplary embodiments of the invention are shown. However, the invention is not limited to the exemplary embodiments described herein, and may be embodied in other forms. Rather, exemplary embodiments described herein are provided to thoroughly and completely explain the disclosed contents and to sufficiently transfer the ideas of the invention to a person of ordinary skill in the art.

In the drawings, the thicknesses of layers and regions are exaggerated for clarity. It is to be noted that when a layer is referred to as being “on” another layer or substrate, it can be directly formed on the other layer or substrate or can be formed on the other layer or substrate with a third layer interposed therebetween. Like elements are denoted by like reference numerals throughout the specification. As used herein, connected may refer to elements being physically and/or electrically connected to each other.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention. Spatially relative terms, such as “below,” “lower,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” relative to other elements or features would then be oriented “above” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

A liquid crystal display having an embedded microcavity (“EM”) structure is a device in which a sacrificial layer as a photoresist is formed, a supporting member is coated thereon, then the sacrificial layer is removed by an ashing process, and a liquid crystal used for displaying the image is filled in an empty space formed by removal of the sacrificial layer. In the liquid crystal display having the EM structure, when the sacrificial layer and the supporting member are formed with the same material, the supporting member may be damaged during removal of the sacrificial layer.

Hereinafter, the invention will be described in detail with reference to the accompanying drawings.

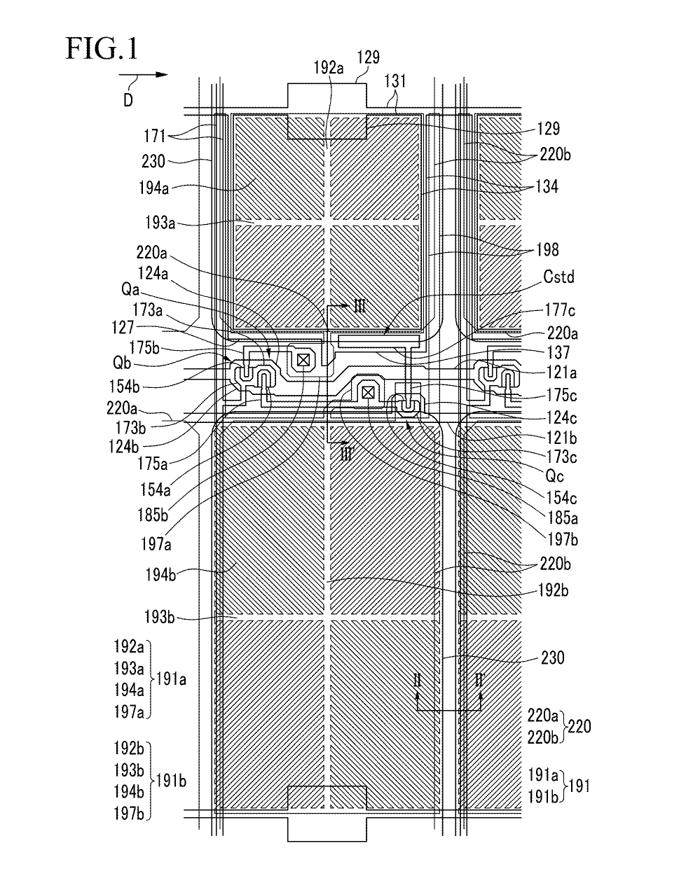

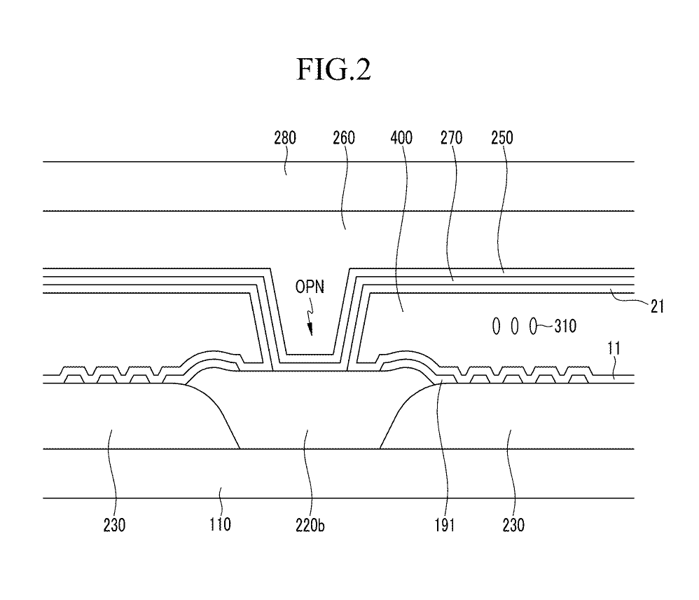

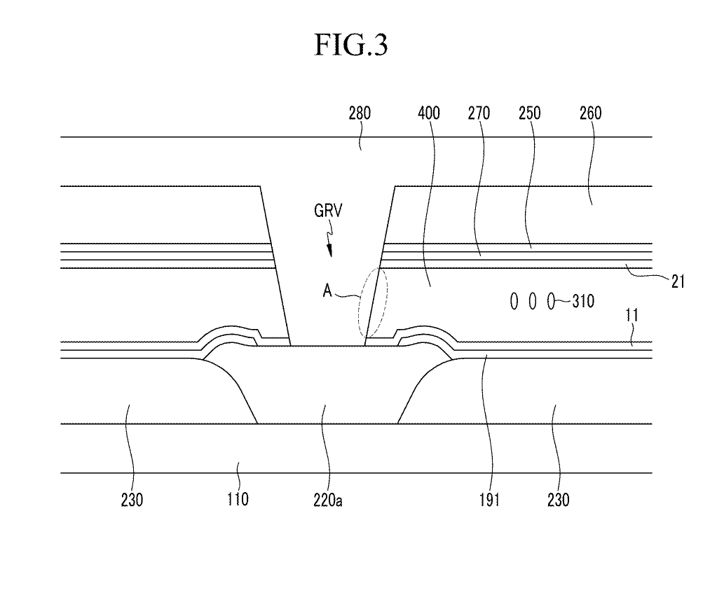

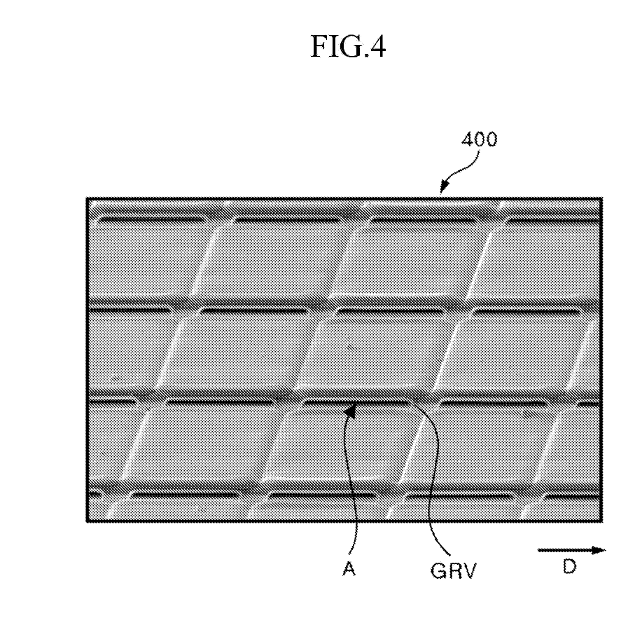

FIG. 1 is a top plan view of an exemplary embodiment of a liquid crystal display according to the invention. FIG. 2 is a cross-sectional view taken along line II-II′ of FIG. 1. FIG. 3 is a cross-sectional view taken along line III-III′ of FIG. 1. FIG. 4 is a perspective view of an exemplary embodiment of a microcavity layer in FIG. 1 to FIG. 3 according to the invention.

Referring FIG. 1 to FIG. 3, thin film transistors Qa, Qb and Qc are on a substrate 110. The substrate may include transparent glass or plastic.

One or more color filters 230 is on the thin film transistors Qa, Qb and Qc. A light blocking member 220 may be between neighboring color filters 230.

A pixel electrode 191 is disposed on the color filter 230, and the pixel electrode 191 is electrically connected to a terminal of the thin film transistors Qa and Qb through contact holes 185a and 185b.

FIG. 2 and FIG. 3 are the cross-sectional views taken along the lines II-II′ and III-III′ of FIG. 1, respectively, however the structure or elements between the substrate 110 and the color filter 230 shown in FIG. 1 are omitted in FIG. 2 and FIG. 3 for convenience of explanation. In reality, a portion of the elements of the thin film transistors Qa, Qb and Qc is between the substrate 110 and the color filter 230 shown in FIG. 2 and FIG. 3.

The pixel electrode 191 may have a longitudinal axis, for example, extending in a column (vertical) direction in FIG. 1. A longitudinal axis of the color filter 230 is extended in the column direction of the pixel electrode 191, such as being parallel to the longitudinal axis of the pixel electrode 191. Each of the color filters 230 may display one of primary colors such as three primary colors of the red, green and blue. However, the invention is not limited to three primary colors such as red, green and blue, and the color filters 230 may display one of cyan, magenta, yellow and white-based colors.

A lower alignment layer 11 is on the pixel electrode 191, and may be a vertical alignment layer. The lower alignment layer 11 as a liquid crystal alignment layer, may include polyamic acid, polysiloxane or polyimide, but is not limited thereto or thereby.

A microcavity layer 400 is on the lower alignment layer 11. The microcavity layer 400 includes a liquid crystal material including liquid crystal molecules 310 therein, and the microcavity layer 400 has a liquid crystal injection hole A. In the exemplary embodiment, the liquid crystal material may be injected to the microcavity layer 400, through the injection hole A, such as by using a capillary force.

An upper alignment layer 21 is disposed on the microcavity layer 400. A common electrode 270 and an overcoat 250 are on the upper alignment layer 21. The common electrode 270 receives a common voltage and generates an electric field along with the pixel electrode 191 which is applied with the data voltage, to determine an inclination direction of the liquid crystal molecules 310 disposed in the microcavity layer 400 between the two electrodes 191 and 270. The common electrode 270 and the pixel electrode 191 form a capacitor (hereafter referred to as “a liquid crystal capacitor”) to maintain the applied voltage after a thin film transistor is turned off. The overcoat 250 may include silicon nitride (SiNx) or silicon oxide (SiO₂).

A supporting member 260 is disposed on the overcoat 250. The supporting member 260 may include silicon oxycarbide (SiOC), a photoresist or an organic material. When the supporting member 260 includes silicon oxycarbide (SiOC), a chemical vapor deposition method may be used to form the supporting member 260, and when the supporting member 260 includes the photoresist, a coating method may be applied to form the supporting member 260. Among layers that may be formed through the chemical vapor deposition, the silicon oxycarbide (SiOC) has high transmittance and low layer stress, thereby not allowing the formed layer to maintain physical and/or mechanical properties thereof. Accordingly, in the exemplary embodiment, the supporting member 260 includes silicon oxycarbide (SiOC) such that light is well transmitted and the layer is stable.

A groove GRV may pass partially or completely through a thickness of the microcavity layer 400, the upper alignment layer 21, the common electrode 270, the overcoat 250 and the supporting member 260.

Next, the microcavity layer 400 will be described with reference to FIG. 2 to FIG. 4.

Referring to FIG. 2 to FIG. 4, the microcavity layer 400 is divided by a plurality of grooves GRV disposed overlapping a gate line 121a. The gate line 121a has a longitudinal axis which extends in a direction D indicated in FIG. 1. A collective microcavity layer member may be divided into a plurality of microcavity layers 400, and the plurality of microcavity layers 400 may be disposed in the direction D in which the gate line 121a extends. The plurality of microcavity layers 400 may respectively correspond to pixel areas of the liquid crystal display. Groups of microcavity layers 400 may be arranged in the column direction.

The groove GRV may have a longitudinal axis which extends in the direction D. The groove GRV between adjacent microcavity layers 400, may be disposed extending in the direction D in which the gate line 121a longitudinally extends, such as being parallel to the direction D. The liquid crystal injection hole A of the microcavity layer 400 forms a region corresponding to a boundary of the groove GRV and the microcavity layer 400.

The liquid crystal injection hole A may have a longitudinal axis, and the longitudinal axis of the liquid crystal injection hole A may extend in a direction in which the groove GRV extends, such as being parallel to the longitudinal axis of the groove GRV. Also, an opening part OPN between microcavity layers 400 adjacent to each other in the direction D in which the gate line 121a longitudinally extends, may be covered by the supporting member 260 as shown in FIG. 2. A portion of the overcoat 250 and/or the common electrode 270 may also be in the opening OPN.

The liquid crystal injection hole A included in the microcavity layer 400 is disposed between the supporting member 260 and the pixel electrode 191.

In the exemplary embodiment, a longitudinal axis of the groove GRV extends in the direction D in which the gate line 121a extends. However as another exemplary embodiment, the longitudinal axis of a plurality of grooves GRV may be extended in a direction in which a longitudinal axis of a data line 171 extends, such as the column direction. Groups of the microcavity layers 400 may be disposed in the direction D (e.g., a row direction). The longitudinal axis of the liquid crystal injection hole A may be extended in the same direction as the extension direction of the groove GRV which is the direction in which the longitudinal axis of the data line 171 extends.

A capping layer 280 is disposed on the supporting member 260. The capping layer 280 contacts an upper surface and a side surface of the supporting member 260, and the capping layer 280 covers the liquid crystal injection hole A of the microcavity layer 400 exposed by the groove GRV. The capping layer 280 may include a thermal hardening resin, silicon oxycarbide (SiOC) or graphene, but the invention is not limited thereto or thereby.

When the capping layer 280 includes graphene, the graphene has transmission resistance against a gas including helium, thereby allowing the capping layer 280 to cap the liquid crystal injection hole A such that the liquid crystal material is sealed within the microcavity layer 400. The capping layer 280 may include a carbon combination such that the liquid crystal material is not contaminated even if the capping layer 280 contacts the liquid crystal material.

Also, the graphene protects the liquid crystal material from exposure to oxygen or moisture from outside.

In the exemplary embodiment, the liquid crystal material is injected through the liquid crystal injection hole A of the microcavity layer 400 and the liquid crystal injection hole A of the microcavity layer 400 is sealed by the capping layer 280, thereby forming a liquid crystal display without employing an upper substrate.

An additional overcoat (not shown) including an organic layer or an inorganic layer may be disposed on the capping layer 280. The capping layer 280 further protects the liquid crystal molecules 310 at an interior of the microcavity layer 400 from an external impact, such that the liquid crystal molecules 310 are not undesirably flattened by the external impact.

Referring again to FIG. 1 to FIG. 3, the exemplary embodiment of the liquid crystal display according to the invention will be further described.

Referring to FIG. 1 to FIG. 3, a plurality of gate conductors including the gate line 121a, a step-down gate line 121b and a storage electrode line 131 are on the substrate 110. The liquid crystal display may include a plurality of gate lines 121a, a plurality of step-down gate lines 121b and a plurality of storage electrode lines 131 on the substrate 110. The substrate 110 may include transparent glass or plastic.

The gate lines 121a and the step-down gate lines 121b have a longitudinal axis that extends in a mainly transverse (horizontal in FIG. 1) direction, and transmit gate signals. The gate line 121a includes a first gate electrode 124a and a second gate electrode 124b protruding upward and downward in a plan view, respectively, from a main portion of the gate line 121. The step-down gate line 121b includes a third gate electrode 124c protruding upward in the plan view. The first gate electrode 124a and the second gate electrode 124b are connected to and continuous with each other to collectively form one protrusion of the gate line 121a.

The storage electrode lines 131 have a longitudinal axis that extends mainly in the transverse direction, and transfer a predetermined voltage such as a common voltage. Each storage electrode line 131 includes a storage electrode 129 protruding upward and downward in the plan view, a pair of longitudinal portions 134 extending substantially perpendicular to the gate lines 121a and 121b and downward in the plan view, and a transverse portion 127 connecting ends of a pair of longitudinal portions 134. The transverse portion 127 includes a capacitive electrode 137 extending downward in the plan view.

A gate insulating layer (not shown) is on the gate conductors 121a, 121b and 131.

A plurality of semiconductor stripes (not shown) that may include amorphous silicon or crystallized silicon are on the gate insulating layer. The semiconductor stripes having a longitudinal axis that mainly extends in the column direction, and include first and second semiconductors 154a and 154b protruding toward the first and second gate electrodes 124a and 124b and connected to each other, and a third semiconductor 154c disposed on the third gate electrode 124c.

A plurality of pairs of ohmic contacts (not shown) are on the semiconductors 154a, 154b and 154c. The ohmic contacts may include silicide or n+ hydrogenated amorphous silicon doped with an n-type impurity at a high concentration.

A data conductor including the data line 171, a first drain electrode 175a, a second drain electrode 175b and a third drain electrode 175c on the ohmic contacts. The liquid crystal display may include a plurality of data lines 171, a plurality of first drain electrodes 175a, a plurality of second drain electrodes 175b and a plurality of third drain electrodes 175c on the ohmic contacts.

The data lines 171 transmit data signals, and the longitudinal axis of the data lines 171 extends in the column direction thereby intersecting the gate line 121a and the step-down gate line 121b. Each data line 171 includes a first source electrode 173a and a second source electrode 173b extending toward the first gate electrode 124a and the second gate electrode 124b, respectively, and connected to and continuous with each other.

The first drain electrode 175a, the second drain electrode 175b and a third drain electrode 175c each include a first end having a wide planar area and a second end having a relatively long and evenly shaped bar are. Bar ends of the first drain electrode 175a and the second drain electrode 175b are partially enclosed by the first source electrode 173a and the second source electrode 173b, respectively. The wide end of the first drain electrode 175a extends again, thereby defining the third source electrode 173c curved with a “U” shape. A wide end 177c of the third drain electrode 175c overlaps the capacitive electrode 137 thereby forming a step-down capacitor Cstd, and the bar end of the third drain electrode 175c is partially enclosed by the third source electrode 173c.

The first gate electrode 124a, the first source electrode 173a, and the first drain electrode 175a form a first thin film transistor Qa along with the first semiconductor 154a, the second gate electrode 124b, the second source electrode 173b, and the second drain electrode 175b form a second thin film transistor Qb along with the second semiconductor 154b, and the third gate electrode 124c, the third source electrode 173c, and the third drain electrode 175c form a third thin film transistor Qc along with the third semiconductor 154c.

The semiconductor stripes including the first semiconductor 154a, the second semiconductor 154b and the third semiconductor 154c, except for the channel region between the source electrodes 173a, 173b and 173c, and the drain electrodes 175a, 175b and 175c, have substantially the same plane shape as the data conductors 171a, 171b, 173a, 173b, 173c, 175a, 175b and 175c and the underlying ohmic contacts.

The first semiconductor 154a includes a portion that is not covered by the first source electrode 173a and the first drain electrode 175a, and the portion is exposed between the first source electrode 173a and the first drain electrode 175a. The second semiconductor 154b includes a portion that is not covered by the second source electrode 173b and the second drain electrode 175b, and the portion is exposed between the second source electrode 173b and the second drain electrode 175b. The third semiconductor 154c includes a portion that is not covered by the third source electrode 173c and the third drain electrode 175c, and the portion is exposed between the third source electrode 173c and the third drain electrode 175c.

A lower passivation layer (not shown) including an inorganic insulator such as silicon nitride or silicon oxide is on the data conductors 171a, 171b, 173a, 173b, 173c, 175a, 175b and 175c and the exposed portions of the first, second, and third semiconductors 154a, 154b and 154c.

The color filter 230 may be disposed on the lower passivation layer. The color filter 230 is disposed at most regions except where the first thin film transistor Qa, the second thin film transistor Qb and the third thin film transistor Qc are disposed. However, the longitudinal axis of the color filter 230 may extend in the column direction along the space between the data lines 171 that are adjacent to each other. In the exemplary embodiment, the color filter 230 is under the pixel electrode 191, however the color filter may be above the common electrode 270.

The light blocking member 220 is disposed on a region where the color filter 230 is not disposed, and overlaps a portion of the color filter 230. The light blocking member 220 includes a first light blocking member 220a and a second light blocking member 220b. The first light blocking member 220a extends substantially parallel with and upward and downward from the gate line 121a and the step-down line 121b, and covers the region including the first thin film transistor Qa, the second thin film transistor Qb and the third thin film transistor Qc. The second light blocking member 220b extends substantially parallel to the data line 171.

The light blocking member 220 may be otherwise referred to as a black matrix, and prevents light leakage.

The lower passivation layer and the light blocking member 220 have a plurality of contact holes 185a and 185b extending through thicknesses thereof, and exposing the first drain electrode 175a and the second drain electrode 175b.

Also, the pixel electrode 191 including a first sub-pixel electrode 191a and a second sub-pixel electrode 191b is on the color filter 230 and the light blocking member 220. The first sub-pixel electrode 191a and the second sub-pixel electrode 191b are divided with respect to the gate line 121a and the step-down gate line 121b, and are disposed above and below the gate line 121a and the step-down gate line 121 b in the plan view, such that the first and second sub-pixel electrodes 191a and 191b are adjacent to each other in the column direction. A length of the second sub-pixel electrode 191b in the column direction is greater than a length of the first sub-pixel electrode 191a in the column direction. The length of the second sub-pixel electrode 191b may be about one to three times that of the first sub-pixel electrode 191a.

Each overall planar shape of the first sub-pixel electrode 191a and the second sub-pixel electrode 191b is a quadrangle. The first sub-pixel electrode 191a and the second sub-pixel electrode 191b respectively include a cross stem including transverse stems 193a and 193b, and longitudinal stems 192a and 192b crossing the transverse stems 193a and 193b. Also, the first sub-pixel electrode 191a and the second sub-pixel electrode 191b respectively include a plurality of minute branches 194a and 194b, a lower protrusion 197a, and an upper protrusion 197b.

The first and second sub-pixel electrodes 191 a and 191 b are divided into four sub-regions by the transverse stems 193a and 193b and the longitudinal stems 192a and 192b. The minute branches 194a and 194b obliquely extend from the transverse stems 193a and 193b and the longitudinal stems 192a and 192b, and the extending direction of minute branches 194a and 194b forms an angle of about 45 degrees or 135 degrees with the gate lines 121a and 121b and/or the transverse stems 193a and 193b. Also, the minute branches 194a and 194b of two neighboring sub-regions may be crossed or intersect each other, for example, to form an angle of about 90 degrees.

In the exemplary embodiment, the first sub-pixel electrode 191a further includes an outer stem extending in both in the row and column directions, enclosing a periphery of the first sub-pixel electrode 191a and connecting distal ends of the minute branches 194a to each other. The second sub-pixel electrode 191b further includes a transverse portion disposed at upper and lower portions of the second sub-pixel electrode 191b, the transverse portion connecting distal ends of a portion of the minute branches 194b to each other, and right and left longitudinal portions 198 disposed on the right and left sides of the first sub-pixel electrode 191a. The right and left longitudinal portions 198 may reduce or effectively prevent capacitive coupling between the data line 171 and the first sub-pixel electrode 191a.

The lower alignment layer 11, the microcavity layer 400, the upper alignment layer 21, the common electrode 270, the overcoat 250 and the capping layer 280 are on the pixel electrode 191, and the description of these elements was previously given such that further description is omitted.

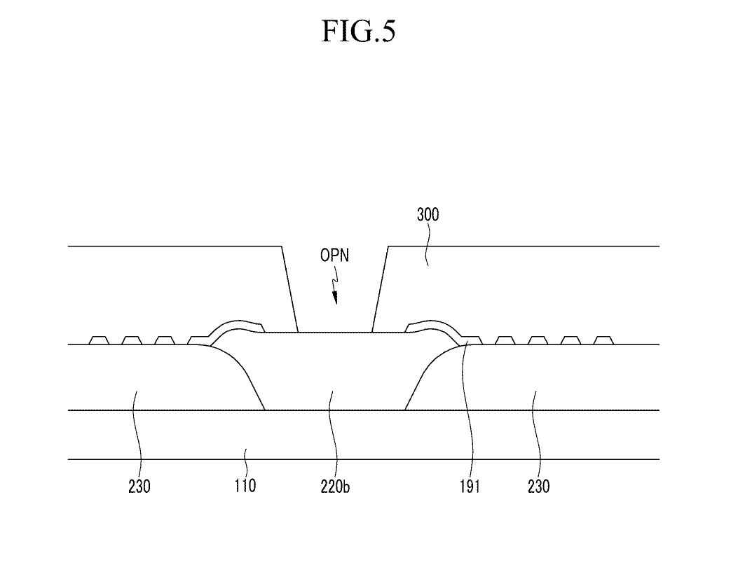

FIG. 5 to FIG. 14 are cross-sectional views of an exemplary embodiment of a manufacturing method of a liquid crystal display according to the invention.

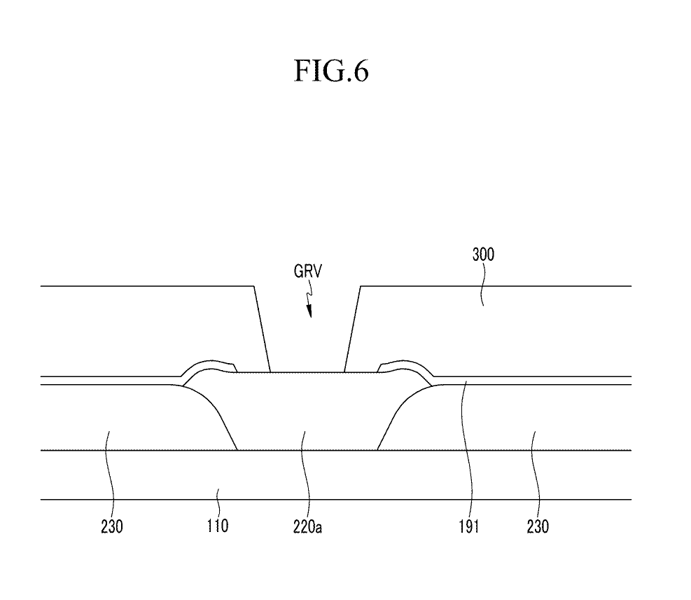

Referring to FIG. 5 and FIG. 6 as cross-sectional views taken along line II-II′ and III-III′ of FIG. 1, respectively, a thin film transistor (not shown) and a lower passivation layer (not shown) are formed on a substrate 110, and a color filter 230 is formed on the lower passivation layer. The substrate 110 may include transparent glass or plastic. The color filter 230 may be formed by a photo-process, and a light blocking member 220 and 220b is formed between the neighboring color filters 230.

Next, a pixel electrode 191 including minute branches is formed on the color filter 230. The pixel electrode 191 may include a transparent conductor such as indium tin oxide (“ITO”) or indium zinc oxide (“IZO”).

A sacrificial layer 300 including silicon oxycarbide (SiOC) or a photoresist is formed on the pixel electrode 191. The sacrificial layer 300 may include an organic material as well as silicon oxycarbide (SiOC) or the photoresist.

When the sacrificial layer 300 includes silicon oxycarbide (SiOC), the chemical vapor deposition method may be used, and when the sacrificial layer 300 includes the photoresist, the coating method may be applied. The sacrificial layer 300 is patterned to form a groove GRV having a longitudinal axis extending in a direction parallel to a longitudinal axis of a signal line connected to a terminal of the thin film transistor, and to form an opening part OPN having a longitudinal axis extending in a direction substantially perpendicular to the longitudinal axis of the groove GRV.

When the sacrificial layer 300 includes silicon oxycarbide (SiOC) by using the chemical vapor deposition method, a taper angle of more than about 72 degrees with respect to an upper surface of the substrate 110 may be realized in a cross-sectional profile of the sacrificial layer 300. Particularly, when realizing the taper angle of the sacrificial layer 300 of more than about 80 degrees, after the sacrificial layer 300 is removed in subsequent processes, the liquid crystal material fills a space once occupied by the sacrificial layer 300, thereby reducing distortion of the liquid crystal in the driving. Also, a cell gap of the liquid crystal display is determined by a coating thickness of the sacrificial layer 300. A deposition of the sacrificial layer 300 to be more than several hundred angstroms has advantages over using the chemical vapor deposition method instead of the coating method. Simply, if the sacrificial layer 300 is deposited to be more than several hundred angstroms by the coating method, the process time is greatly increased, thereby being non-efficient in comparison to the chemical vapor deposition method.

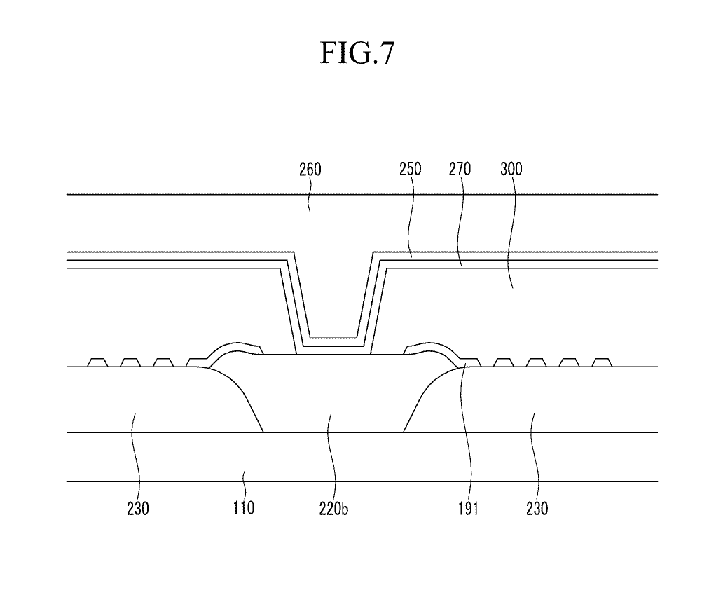

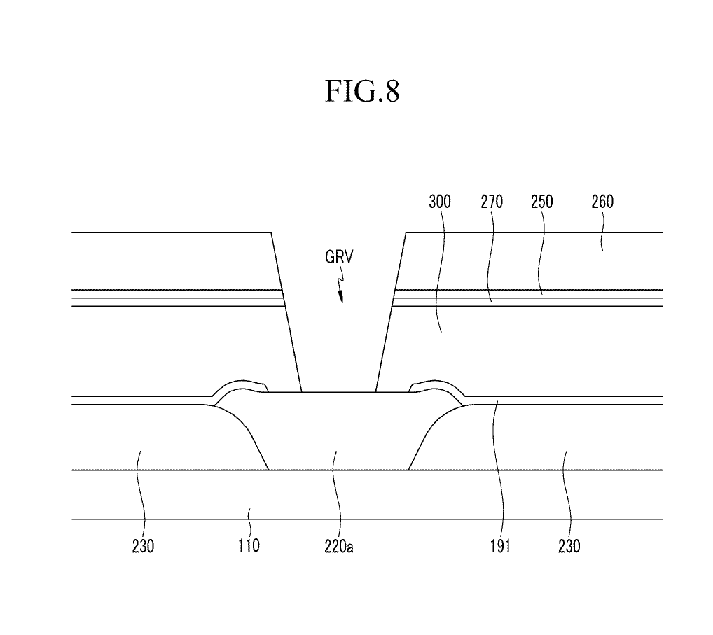

Referring to FIG. 7 and FIG. 8 as cross-sectional views taken along line II-II′ and III-III′ of FIG. 1, respectively, a common electrode 270, an overcoat 250 and a supporting member 260 are sequentially formed on the sacrificial layer 300.

The common electrode 270 may include the transparent conductor such as ITO or IZO, and the overcoat 250 may include silicon nitride (SiNx) or silicon oxide (SiO₂). The supporting member 260 in the exemplary embodiment may include a different material from the sacrificial layer 300. In detail, when the sacrificial layer 300 includes silicon oxycarbide (SiOC), the supporting member 260 may include a different material from silicon oxycarbide (SiOC), and when the sacrificial layer 300 includes a different material from silicon oxycarbide (SiOC), the supporting member 260 is formed of silicon oxycarbide (SiOC).

When the supporting member 260 includes silicon oxycarbide (SiOC), the silicon oxycarbide (SiOC) has low reactivity with the liquid crystal material including liquid crystal molecules 310 such that the stability of the liquid crystal display may be improved, and excellent thermal stability may be obtained compared with other materials.

When the supporting member 260 includes a different material from that of the sacrificial layer 300, selective removal is possible when removing the sacrificial layer 300 such that damage to the supporting member 260 may be reduced or effectively prevented.

The common electrode 270, the overcoat 250 and the supporting member 260 may be formed on a portion or an entire area of the sacrificial layer 300. The common electrode 270, the overcoat 250 and the supporting member 260 are formed to fill the opening part OPN. However, to obtain a path to remove the sacrificial layer 300 at the groove GRV, the common electrode 270, the overcoat 250 and the supporting member 260 are removed in the portion overlapping the groove GRV. However, if a path to remove the sacrificial layer 300 is otherwise provided, portions of the common electrode 270, the overcoat 250 and the supporting member 260 may be maintained inside the groove GRV.

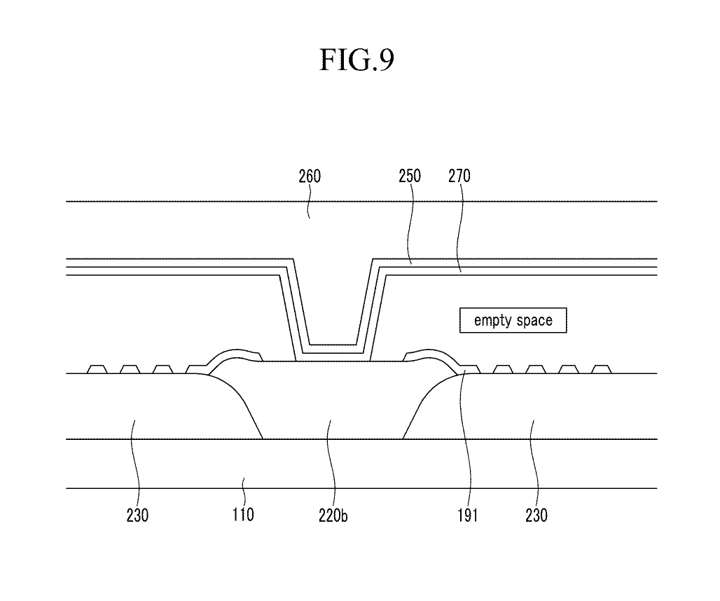

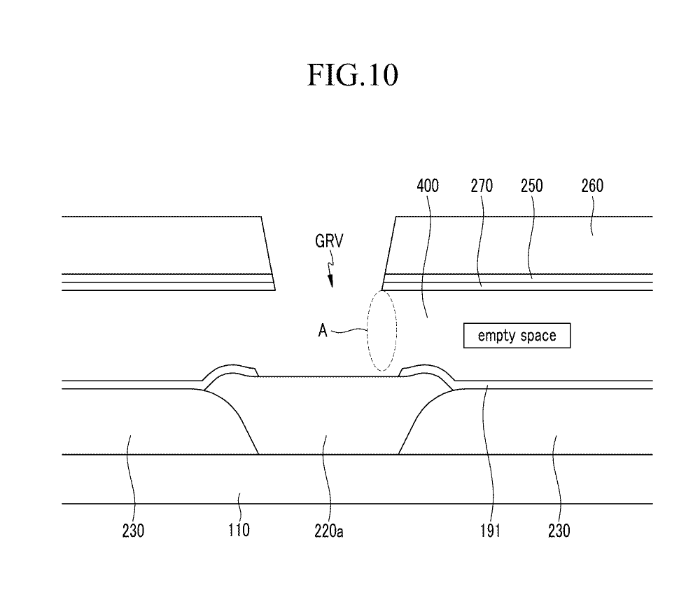

Referring to FIG. 9 and FIG. 10 as cross-sectional views taken along line II-II′ and III-III′ of FIG. 1, respectively, the sacrificial layer 300 is removed through the groove GRV by an ashing process, such as an oxygen (O₂) ashing process. A microcavity layer 400 having a liquid crystal injection hole A is thereby formed through the removal of the sacrificial layer 300. The microcavity layer 400 includes an empty space at which the sacrificial layer 300 has been removed. The liquid crystal injection hole A may be formed to have a longitudinal axis extending in the direction parallel to the longitudinal axis of the signal line connected to one terminal of the thin film transistor. The liquid crystal injection hole A has an initial height defined by a distance between the common electrode 270 and the light blocking member 220a, and perpendicular to the substrate 110.

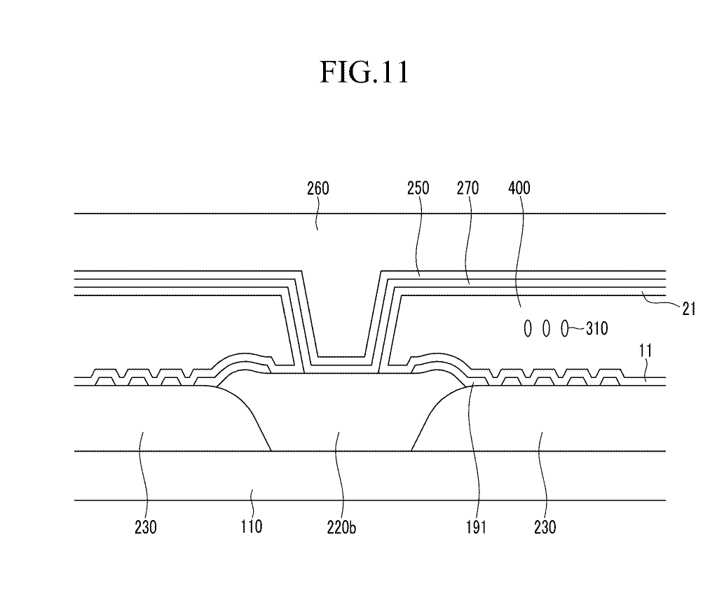

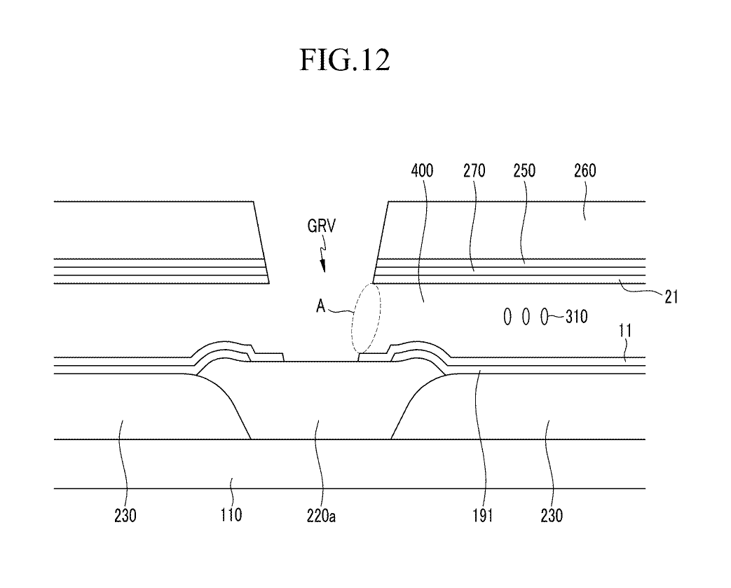

Referring to FIG. 11 and FIG. 12 as cross-sectional views taken along line II-II′ and III-III′ of FIG. 1, respectively, an alignment material is injected through the groove GRV and the liquid crystal injection hole A to form alignment layers 11 and 21 on the pixel electrode 191 and the common electrode 270. Portions of the alignment layers 11 and 21 located at the liquid crystal injection hole A may reduce the height of the liquid crystal injection hole A.

Next, a liquid crystal material 310 is injected into the microcavity layer 400 through the groove GRV and the liquid crystal injection hole A, such as by using a capillary force. Here, the liquid crystal injection hole A may have the reduced height compared with the initial liquid crystal injection hole A, due to the formation of the alignment layers 11 and 21.

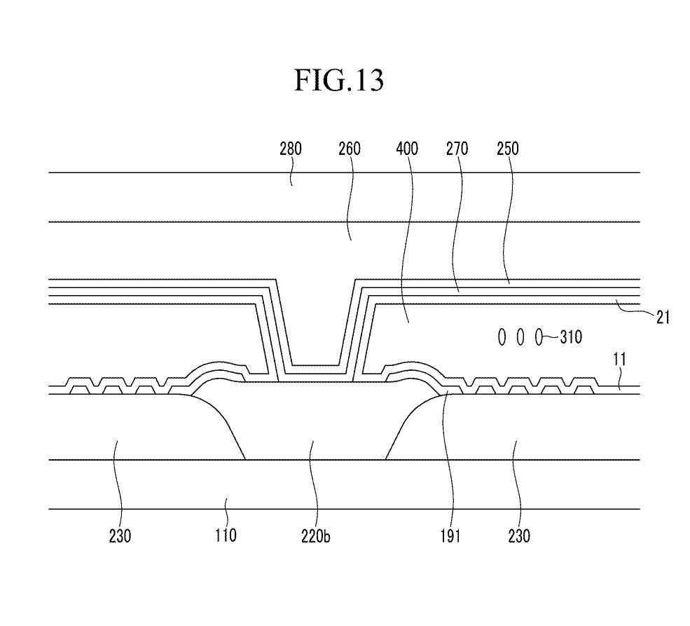

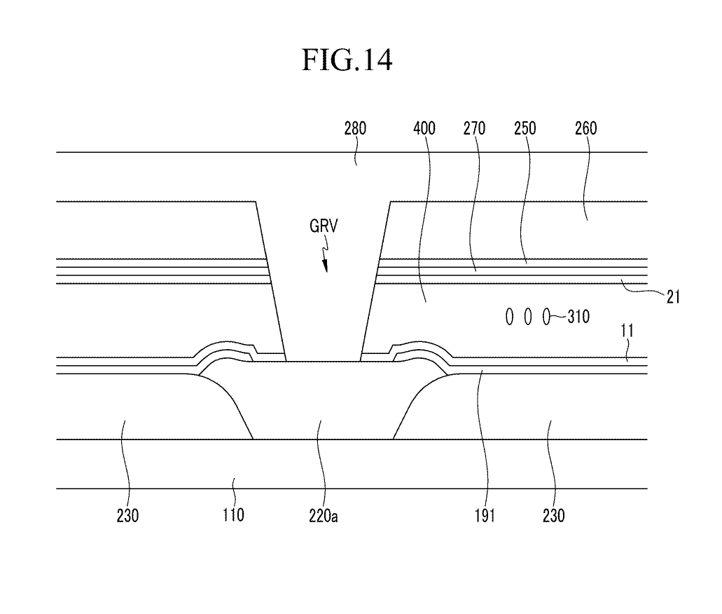

Referring to FIG. 13 and FIG. 14 as cross-sectional views taken along line II-II′ and III-III′ of FIG. 1, respectively, the liquid crystal material including the liquid crystal molecules 310 injected into the microcavity layer 400 may be exposed to outside the microcavity layer 400 and/or the liquid crystal display through the liquid crystal injection hole A, since the liquid crystal injection hole A is open and exposed to the outside by the groove GRV. To close and seal the open the liquid crystal injection hole A, a capping layer 280 covering the liquid crystal injection hole A is formed. The capping layer 280 contacts the upper surface and the side wall of the supporting member 260, and contacts side surfaces of the alignment layers 11 and 21, the common electrode 270 and the overcoat exposed in the groove GRV. The capping layer 280 overlaps an entire of the liquid crystal injection hole A of the microcavity layer 400 exposed by the groove GRV. The capping layer 280 may include the thermal hardening resin, silicon oxycarbide (SiOC), or a graphene. The capping layer 280 may also planarize a surface of the liquid crystal display.

In the exemplary embodiment, the liquid crystal material is injected through the liquid crystal injection hole A of the microcavity layer 400 and the liquid crystal injection hole A is sealed within the microcavity layer 400, thereby forming a liquid crystal display without employing an upper substrate.

In one or more embodiments of the liquid crystal display and the manufacturing method thereof according to the invention, materials for the sacrificial layer and the supporting member are designed in consideration of physical characteristics and aspects which affected during forming of the liquid crystal display. To reduce or effectively prevent damage to the supporting member when removing the sacrificial layer, only one of the sacrificial layer and the supporting member includes silicon oxycarbide, but the invention is not limited thereto or thereby.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A liquid crystal display comprising:
a substrate;
a thin film transistor on the substrate;
a pixel electrode which is connected to a first terminal of the thin film transistor;
a microcavity layer on the pixel electrode and comprising an injection hole through which material is provided to the microcavity layer;
a supporting layer on the microcavity layer and comprising silicon oxycarbide; and
a capping layer on the supporting layer, wherein the capping layer covers the injection hole.

2. The liquid crystal display of claim 1, wherein the capping layer contacts an upper surface of the supporting layer.

3. The liquid crystal display of claim 2, wherein the microcavity layer comprises a liquid crystal material.

4. The liquid crystal display of claim 3, further comprising a plurality of pixel areas,
wherein the microcavity layer comprises a plurality of regions corresponding to the pixel areas,
wherein a groove is between adjacent regions of the microcavity layer, and
wherein the capping layer covers the groove.

5. The liquid crystal display of claim 4, further comprising a signal line which is connected to a second terminal of the thin film transistor,
wherein the groove extends in a first direction parallel to an extending direction of the signal line.

6. The liquid crystal display of claim 5, further comprising an opening part between regions of the microcavity layer which are adjacent to each other in the first direction, wherein the opening part extends in a second direction which intersects the first direction, and
wherein the supporting layer covers the opening part.

7. The liquid crystal display of claim 1, further comprising a common electrode between the microcavity layer and the supporting layer.

8. The liquid crystal display of claim 1, further comprising an alignment layer between the pixel electrode and the microcavity layer, and between the supporting layer and the microcavity layer.

9. A liquid crystal display comprising:
a substrate;
a thin film transistor on the substrate;
a pixel electrode which is connected to a first terminal of the thin film transistor;
a microcavity layer on the pixel electrode and comprising an injection hole through which material is provided to the microcavity layer,
a supporting layer on the microcavity layer; and
a capping layer on the supporting layer, wherein the capping layer covers the injection hole and contacts an upper surface of the supporting layer.

10. The liquid crystal display of claim 9, wherein the supporting layer comprises silicon oxycarbide.

11. The liquid crystal display of claim 10, wherein the microcavity layer comprises a liquid crystal material.

12. The liquid crystal display of claim 11, further comprising a plurality of pixel areas,
wherein the microcavity layer comprises a plurality of regions corresponding to the pixel areas,
a groove is between adjacent regions of the microcavity layer, and
the capping layer covers the groove.

13. The liquid crystal display of claim 12, further comprising a signal line which is connected to a second terminal of the thin film transistor,
wherein the groove extends in a first direction parallel to an extending direction of the signal line.

14. The liquid crystal display of claim 13, further comprising an opening part between regions of the microcavity layer which are adjacent to each other in the first direction, wherein the opening part extends in a second direction which intersects the first direction, and
the supporting covers the opening part.

15. The liquid crystal display of claim 9, further comprising
a common electrode between the microcavity layer and the supporting layer.

16. The liquid crystal display of claim 9, further comprising
an alignment layer between the pixel electrode and the microcavity layer, and between the supporting layer and the microcavity layer.

17. A method manufacturing a liquid crystal display, the method comprising:
providing a thin film transistor on a substrate;
providing a pixel electrode on the thin film transistor;
providing a sacrificial layer on the pixel electrode;
providing a supporting layer on the sacrificial layer;
removing the sacrificial layer, to form a microcavity layer comprising an injection hole through which a material is provided to the microcavity layer;
injecting a liquid crystal material to the microcavity layer through the injection hole; and
providing a capping layer on the supporting layer,
wherein the capping layer covers the injection hole of the microcavity layer, and
the sacrificial layer and the supporting layer comprise different materials from each other.

18. The method of claim 17, wherein one of the sacrificial layer and the supporting layer comprises silicon oxycarbide.

19. The method of claim 18, wherein the one of the sacrificial layer and the supporting layer comprising silicon oxycarbide is provided by using chemical vapor deposition.

20. The method of claim 19, wherein the one of the sacrificial layer and the supporting layer not comprising silicon oxycarbide is provided by using a photoresist.

21. The method of claim 17, further comprising:
providing a color filter on the thin film transistor; and
providing a light blocking member which overlaps an edge of the color filter,
wherein the injection hole is formed to be disposed along an extension direction of the light blocking member.

22. The method of claim 17, wherein
the capping layer contacts an upper surface of the supporting layer.

23. The method of claim 17, further comprising
providing an alignment layer at an outer wall of the microcavity layer before the injecting the liquid crystal material to the microcavity layer.

24. The method of claim 17, further comprising
providing a common electrode between the sacrificial layer and the supporting layer.
